(19) United States
(12) Patent Application Publication
(10) Pub. No.: US 2024/0023418 A1
(43) Pub. Date: Jan. 18, 2024

(54) DISPLAY MODULE

(71) Applicant: Wuhan China Star Optoelectronics Semiconductor Display Technology Co., Ltd., Wuhan, Hubei (CN)

(72) Inventor: Wenhua YANG, Wuhan, Hubei (CN)

(73) Assignee: Wuhan China Star Optoelectronics Semiconductor Display Technology Co., Ltd., Wuhan, Hubei (CN)

(21) Appl. No.: 17/434,066

(22) PCT Filed: Aug. 3, 2021
(86) PCT No.: PCT/CN2021/110171

§ 371 Date: Aug. 26, 2021

(30) Foreign Application Priority Data
May 27, 2021 (CN) 202110587114.0

(51) Int. Cl. H10K 59/80; C08J 5/18

(52) U.S. Cl. CPC H10K 59/8791; H10K 59/8792; C08J 5/18; C08J 2301/12; C08K 5/3475

(57) ABSTRACT

A display module includes a polarizer, the polarizer comprises a first optical film layer, a polarizing layer and a second optical film layer stacked in sequence; and the first optical film layer and the second optical film layer have ultraviolet light resistance. In the embodiments of the present disclosure, the first optical film layer and the second optical film layer with ultraviolet light resistance are respectively arranged on opposite sides of the polarizing layer to improve the color temperature stability of the polarizer before and after sunlight exposure.

### TECHNICAL FIELD

The present disclosure relates to a field of display technology, and more particularly to a display module.

### BACKGROUND

Organic light-emitting diode (OLED) displays are self-luminous displays. Compared with liquid crystal displays (LCD), the OLED displays do not require a backlight, so the OLED displays are lighter and thinner. In addition, the OLED displays further have advantages of high brightness, low power consumption, wide viewing angles, high response speed, and wide operating temperature range, and are increasingly being used in various high-performance display fields.

Light-emitting mechanism of the OLED displays is that under action of an external electric field, electrons and holes are injected into organic electro-luminescence material (EL material) from positive and negative poles, so that the organic light-emitting material undergoes migration, recombination, and attenuation to emit light.

Currently, for the OLED displays, equipment manufacturers have a demand for sunlight. Display panels of the OLED displays have a phenomenon of lowering color temperature after sunlight exposure. If color temperature decrease is too large, the color temperature of the display panels will be yellow after the sun is irradiated, which will affect display effect.

### SUMMARY

Embodiments of the present disclosure provide a display module, which can reduce the color temperature change of a polarizer after sunlight exposure, improve solar resistance performance of the display module, and improve the display effect.

The embodiments of the present disclosure provide a display module. The display module includes a polarizer. The polarizer includes a first optical film layer, a polarizing layer and a second optical film layer stacked in sequence; and the first optical film layer and the second optical film layer have ultraviolet light resistance.

Wherein, the first optical film layer and the second optical film layer are film layers made of same material.

Wherein, the material configured to manufacture the first optical film layer and the second optical film layer includes cellulose triacetate.

Wherein, the polarizer further includes a hardened coating layer; and the hardened coating layer is disposed on a side of the second optical film layer away from the first optical film layer.

Wherein, the polarizer further includes a first glue layer, a compensation layer and a second glue layer stacked in sequence; and the first optical film layer is disposed on a side of the second glue layer away from the first glue layer.

Wherein, one of the first optical film layer, the polarizing layer, the hardened coating layer, the second optical film layer, the first glue layer, the compensation layer and the second glue layer is doped with an ultraviolet light absorber.

Wherein, the display module further includes a display panel, and the polarizer is disposed on the display panel.

Wherein, the ultraviolet light absorber includes benzotriazole compound.

Wherein, the benzotriazole compound includes a 2-(2′-hydroxy-3′,5′-di-tert-phenyl)-5-chloro-benzotriazole, and a corresponding doping ratio is 1-3%; or
the benzotriazole compounds includes a 2-(2′-hydroxy-5′-methylphenyl) benzotriazole, and a corresponding doping ratio is 0.1-0.5%.

Wherein, an optimal doping ratio of the 2-(2′-hydroxy-3′,5′-di-tert-phenyl)-5-chloro-benzotriazole is 2%, and an optimal doping ratio of the 2-(2′-hydroxy-5′-methylphenyl)benzotriazole is 0.3%.

Wherein, a material configured to manufacture the first optical film layer and the second optical film layer includes cellulose triacetate; the first optical film layer, the second optical film layer and the hardened coating layer are doped with the ultraviolet light absorber; the ultraviolet light absorber includes the 2-(2′-hydroxy-5′-methylphenyl) benzotriazole, and the doping ratio of the 2-(2′-hydroxy-5′-methylphenyl) benzotriazole is a corresponding optimal doping ratio.

Wherein, the ultraviolet light absorber includes a light stabilizer.

Wherein, the light stabilizer includes a 4-benzoyloxy-2,2,6,6-tetramethylpiperidine, and a corresponding doping ratio is 0-1%; or
the light stabilizer includes a hexamethylphosphoric triamide, and a corresponding doping ratio is 0-0.5%.

Wherein, an optimal doping ratio of the 4-benzoyloxy-2,2,6,6-tetramethylpiperidine is 0.7%, and an optimal doping ratio of the hexamethylphosphoric triamide is 0.4%.

Wherein, the first optical film layer is doped with first ultraviolet light absorber; a process of manufacturing the first optical film layer doped with the first ultraviolet light absorber includes:
mixing the first ultraviolet light absorber and a first optical material according to a first preset ratio;
processing a mixed first optical material by a polymer molding process to form the first optical film layer;
Wherein, the first ultraviolet light absorber is one of the ultraviolet light absorber, the first optical material is a material configured to manufacture the first optical film layer that is not doped with the first ultraviolet light absorber, and the mixed first optical material includes the first ultraviolet light absorber and the first optical material.

Wherein, the first optical material includes cycloolefin polymer or cellulose triacetate.

Wherein, the second optical film layer is doped with an second ultraviolet light absorber; a process of manufacturing the second optical film layer doped with the second ultraviolet light absorber includes:
mixing the second ultraviolet light absorber and a second optical material according to a second preset ratio;
processing a mixed second optical material by a polymer molding process to form the second optical film layer;
Wherein, the second ultraviolet light absorber is one of the ultraviolet light absorber, the second optical material is a material configured to manufacture the second optical film layer that is not doped with the second ultraviolet light absorber, and the mixed second optical material includes the second ultraviolet light absorber and the second optical material.

Wherein, the hardened coating layer is doped with the ultraviolet light absorber; a process of forming the hardened coating layer doped with the ultraviolet light absorber on the second optical film layer includes:
dissolving a third ultraviolet light absorber into a hardened coating material according to a third preset ratio;
coating a dissolved hardened coating material on a side of the second optical film layer away from the polarizing layer, and drying it by a drying process, to form the hardened coating layer on the second optical film layer;
Wherein, the third ultraviolet light absorber is one of the ultraviolet light absorber, the hardened coating material is a material configured to manufacture the hardened coating layer that is not doped with the third ultraviolet light absorber, and the dissolved hardened coating material includes the hardened coating material and the third ultraviolet light absorber.

Wherein, the display module further includes an optically clear adhesive layer and a protective cover plate; the display panel, the polarizer, the optically clear adhesive layer and the protective cover plate are stacked in sequence.

Wherein, the display panel includes an organic light-emitting diode display array.

The embodiments of the present disclosure provide a display module, wherein the display module includes a polarizer, the polarizer includes a first optical film layer, a polarizing layer and a second optical film layer stacked in sequence; and the first optical film layer and the second optical film layer have ultraviolet light resistance. In the embodiments of the present disclosure, the first optical film layer and the second optical film layer with ultraviolet light resistance are respectively arranged on opposite sides of the polarizing layer. Arrangement of multiple optical film layers with ultraviolet light resistance reduces transmittance of ultraviolet light, reduces damage of ultraviolet light to the polarizer, increases the ultraviolet light resistance of the polarizer, and improves color temperature stability of the polarizer before and after sunlight exposure.

### DESCRIPTION OF DRAWINGS

The embodiments of the present disclosure will be described hereinafter with reference to the accompanying drawings, the technical solutions and the beneficial effects of the present disclosure will be obviously.

FIG. 1 is a schematic structural diagram of a polarization module provided by an embodiment of the present disclosure.

FIG. 2 is another schematic diagram of the polarization module provided by an embodiment of the present disclosure.

FIG. 3 is a schematic diagram of a transmission spectrum of a HC-COP layer at 250 nm to 800 nm provided by an embodiment of the present disclosure.

FIG. 4 is a schematic diagram of the transmission spectrum of a HC-TAC layer at 250 nm to 800 nm provided by an embodiment of the present disclosure.

FIG. 5 is a schematic diagram of a comparison of the transmission spectrum of the HC-COP layer and the HC-TAC layer at 250 nm to 800 nm provided by an embodiment of the present disclosure.

FIG. 6 is a schematic diagram of the transmission spectrum of the polarizer formed by using the HC-COP layer and the HC-TAC layer at 250 nm to 800 nm provided by an embodiment of the present disclosure.

FIG. 7 is a schematic diagram of the transmission spectrum of the polarizer formed by the HC-COP layer and the HC-TAC layer at 250 nm to 400 nm provided by an embodiment of the present disclosure.

FIG. 8 is a schematic diagram of the comparison of the corresponding ultraviolet light transmittance when the HC-TAC layer is doped with ultraviolet light absorber or not provided by an embodiment of the present disclosure.

FIG. 9 is yet another schematic diagram of the structure of the display module provided by an embodiment of the present disclosure.

FIG. 10 is still another schematic diagram of the structure of the display module provided by an embodiment of the present disclosure.

### DETAILED DESCRIPTION OF PREFERRED EMBODIMENTS

The following embodiments refer to the accompanying drawings for exemplifying specific implementable embodiments of the present disclosure in a suitable computing environment. It should be noted that the exemplary described embodiments are configured to describe and understand the present disclosure, but the present disclosure is not limited thereto.

In descriptions of the present disclosure, the terms “portrait”, “horizontal”, “length”, “width”, “upper”, “lower”, “front”, “rear”, “left”, “right”, “vertical”, “horizontal”, and other indicated directions or the position relation are based on the orientation or position relation shown in the figures. Only for convenience of describing the present disclosure and the simplification of the description, rather than indicating or implying that the means or elements referred to have a specific orientation, so that the above directions of the present disclosure cannot be understood as limitations. In addition, the terms “first” and “second” are used only for purposes of description, and cannot be understood to indicate or imply a relative importance or to implicitly indicate the number of technical features indicated. Thus, the features “first” and “second” can be expressly or implicitly included in one or more of the features. In the description of the present disclosure, the meanings of “multiple” are two or more, unless specifically limited otherwise.

In addition, reference numerals and/or reference letters can be repeated in different examples, and such repetition is for the purpose of simplicity and clarity, and is not intended to indicate the relationship between the various embodiments and/or arrangements discussed.

For a polarizer in a display module, a traditional optical transmission spectrum is used to study a transmission spectrum in a range of 380 nm to 780 nm, and the research on the transmission spectrum of ultraviolet light in other bands is hardly involved.

The embodiments of the present disclosure provide a display module by studying the transmission spectrum of ultraviolet light in wavelength range of 250 nm to 400 nm.

The embodiments of the present disclosure provide a display module. The polarizer in the display module is used to reduce the transmittance of ultraviolet light and alleviate a problem of excessive reduction in color temperature of traditional display module before and after sunlight exposure, improve color temperature stability, enhance display effect of the display module under sunlight, improve resistance to sunlight (ultraviolet light) of the display module, and improve the display effect of the display module.

The following is a detailed description of the display module provided by the embodiments of the present disclosure.

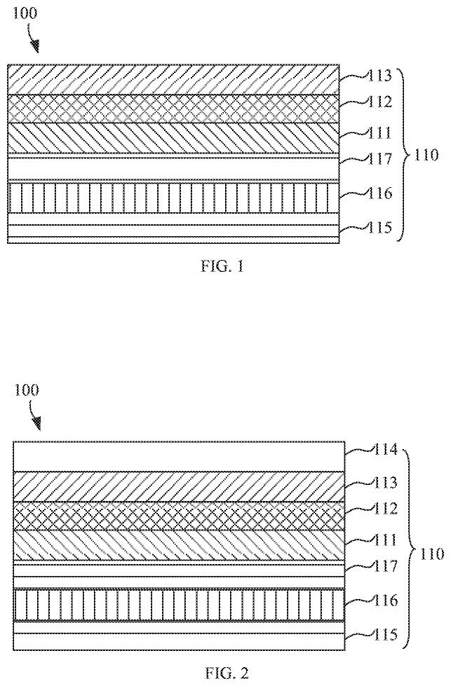

The embodiments of the present disclosure provides the display module, and the display module includes a polarizer. Referring to FIG. 1, the polarizer (POL) 110 of the display module 100 includes a first optical film layer 111, a polarizing layer 112 and a second optical film layer 113 stacked in sequence. Wherein, the second optical film layer 113 is close to a sunlight irradiated side, and the first optical film layer 111 is away from the sunlight irradiated side.

The polarizing layer 112 may be a polyvinyl alcohol (PVA) film layer. The PVA film is a kind of high molecular polymer, which can be dyed with various organic dyes with dichroism. At the same time, it is stretched under certain humidity and temperature conditions to make it absorb dichroic organic dyes to form polarization properties, and after dehydration and drying, an original polarizer film can be formed.

Wherein, the first optical film layer 111 and the second optical film layer 113 have ultraviolet light resistance. Understandably, the optical materials used to make the first optical film layer 111 and the second optical film layer 113 have ultraviolet light resistance, resulting in the first optical film layer 111 and the second optical film layer 113 having ultraviolet light resistance. The first optical film layer 111 and the second optical film layer 113 having ultraviolet light resistance are used to manufacture the polarizer, which improves the ultraviolet light resistance of the polarizer 110 and improves the color temperature stability of the polarizer 110 before and after sunlight exposure. By disposing the first optical film layer 111 and the second optical film layer 113 with ultraviolet light resistance on opposite sides of the polarizing layer 112, the arrangement of multiple optical film layers with ultraviolet light resistance increases the ultraviolet light resistance of the polarizer 110 and improves color temperature stability of the polarizer 110 before and after sunlight exposure.

The first optical film layer 111 may be a cycloolefin polymer (COP) film layer, namely, a material of the first optical film layer 111 includes cycloolefin polymer. The first optical film layer 111 may also be a cellulose triacetate (TAC) film layer, namely, the material of the first optical film layer 111 includes cellulose triacetate. The first optical film layer 111 may also be another film layer with ultraviolet light resistance. The second optical film layer 113 may be a COP film layer, namely, the material of the second optical film layer 113 includes cycloolefin polymer. The second optical film layer 113 may also be a TAC film layer, that is, the material of the second optical film layer 113 includes cycloolefin polymer. The second optical film layer 113 may also be another film layer with ultraviolet light resistance.

The first optical film layer 111 and the second optical film layer 113 may be different film layers. For example, the second optical film layer 113 is a TAC film layer, and the first optical film layer 111 is a COP film layer or other film layers with ultraviolet light resistance. The first optical film layer 111 and the second optical film layer 113 may be the same film layer. For example, the first optical film layer 111 and the second optical film layer 113 are TAC films or all are COP films, or the first optical film layer 111 and the second optical film layer 113 are other films with ultraviolet light resistance. Preferably, the first optical film layer 111 and the second optical film layer 113 in the embodiments of the present disclosure are TAC film layers.

Understandably, the embodiments of the present disclosure has found that the TAC film or the COP film has ultraviolet light resistance through the research of the transmission spectrum of 250 nm to 400 nm wavelength band. And it is found that the ultraviolet light resistance of the TAC film is better than the ultraviolet light resistance of the COP film. Therefore, the first optical film layer 111 and the second optical film layer 113 in the embodiment of the present disclosure preferentially select the TAC film layer.

In order to further improve the ultraviolet light resistance of the polarizer 110, in an embodiment, at least one of the first optical film layer 111, the polarizing layer 112, and the second optical film layer 113 is doped with an ultraviolet light absorber. The doped ultraviolet light absorber further absorbs the ultraviolet light in the sunlight, further reduces the color temperature change of the polarizer 110 after the sunlight is irradiated, and improves the color temperature stability of the polarizer 110 before and after the sunlight is irradiated.

Ultraviolet light absorbers doped in the first optical film layer 111 and/or the polarizing layer 112 and/or the second optical film layer 113 may be same types of ultraviolet light absorbers or different types of ultraviolet light absorbers. When the ultraviolet light absorbers doped in the first optical film layer 111 and/or the polarizing layer 112 and/or the second optical film layer 113 is the same ultraviolet light absorber, doping ratios of the ultraviolet light absorbers in corresponding different film layers can be the same or different. When the ultraviolet light absorbers doped in the first optical film layer 111 and/or the polarizing layer 112 and/or the second optical film layer 113 are different ultraviolet light absorbers, depending on the ultraviolet light absorbers, corresponding doping ratio is also different.

In one embodiment, if the ultraviolet light absorber doped in the first optical film layer 111 and/or the polarizing layer 112 and/or the second optical film layer 113 is the same ultraviolet light absorber, then the doping ratio of the same ultraviolet light absorber is optimal doping ratio so that the ultraviolet light absorber achieves better solubility and better ultraviolet light absorption in the corresponding film layer. If the ultraviolet light absorbers doped in the first optical film layer 111 and/or the polarizing layer 112 and/or the second optical film layer 113 are different ultraviolet light absorbers, the doping ratio of the corresponding different ultraviolet light absorbers is the optical doping ratio of the corresponding ultraviolet light absorbers to achieve better solubility and better ultraviolet light absorption effect of different ultraviolet light absorbers in the corresponding film layer.

Wherein, the ultraviolet light absorber can absorb long-wave ultraviolet light (UV-A, wavelength 315 nm to 400 nm) and medium-wave ultraviolet light (UV-B, wavelength 280 nm to 315 nm) and/or short-wave ultraviolet light (UV-C, wavelength below 280 nm) of the ultraviolet light absorber for absorbing UV-A and UV-B and/or UV-C of sunlight, reducing the transmission rate of UV-A and UV-B and/or UV-C of UV light, and reducing the damage of UV-A and UV-B and/or UV-C of UV light to the polarizer and the damage of EL material. The ultraviolet light bands absorbed by the ultraviolet light absorbers in the embodiments of present disclosure will not be described below.

The ultraviolet light absorbers in the embodiments of the present disclosure include benzotriazole compound. The benzotriazole compound includes a 2-(2′-hydroxy-3′,5′-di-tert-phenyl)-5-chloro-benzotriazole, which can absorb ultraviolet light in the 270 nm to 380 nm band, and the corresponding doping ratio is 1%-3%; or the benzotriazole compounds includes a 2-(2′-hydroxy-5′-methylphenyl) benzotriazole, which can absorb ultraviolet light in the 270 nm to 380 nm band, and the corresponding doping ratio is 0.1-0.5%.

In some cases, the ultraviolet light absorber may include a light stabilizer. Wherein, the light stabilizer is a class of ultraviolet light absorbers corresponding to the trade name of the compound, it can also be understood that the ultraviolet light absorbers include the light stabilizer, or the light stabilizer belongs to a class of ultraviolet light absorbers. The light stabilizer includes a 4-benzoyloxy-2,2,6,6-tetramethylpiperidine, corresponding to the trade name of light stabilizer 744, which can absorb ultraviolet light in the 300 nm to 380 nm band, corresponding to the doping ratio of 0-1%. Or the light stabilizer includes a hexamethyl phosphoryl triamine, corresponding to the trade name of light stabilizer HPT, can absorb ultraviolet light in the band of 270 nm to 380 nm, corresponding to the doping ratio of 0-0.5%.

The doping ratios corresponding to the different ultraviolet light absorbers mentioned above are different. Under the corresponding doping ratio, the different ultraviolet light absorbers and the corresponding raw materials for making the corresponding film layers (the first optical material, the second optical material, the hardened coating material, etc. as described below) can achieve a better mixing and dissolving effect, and under the corresponding doping ratio, they can also achieve a better ultraviolet light absorption effect.

In one embodiment, if the ultraviolet light absorber includes the 2-(2′-hydroxy-3′,5′-di-tert-phenyl)-5-chloro-benzotriazole, the corresponding optimal doping ratio is 2%. If the ultraviolet light absorber includes 2-(2′-hydroxy-5′-methylphenyl)benzotriazole, the corresponding optimum doping ratio is 0.3%. If the ultraviolet light absorber includes the 4-benzoyloxy-2,2,6,6-tetramethylpiperidine, the corresponding optimal doping ratio is 0.7%. If the ultraviolet light absorber includes the hexamethyl phosphoryl triamine, the corresponding optimal doping ratio is 0.4%.

Under the corresponding optimal doping ratio, the different ultraviolet light absorbers and the corresponding raw materials for making the corresponding film layers achieve the best mixing and dissolving effect, and also achieve the best ultraviolet light absorption effect.

It should be noted that above mentioned ultraviolet light absorbers are only examples, and the ultraviolet light absorbers in present disclosure can also be other ultraviolet light absorbers that can absorb UV-A and UV-B bands.

Wherein, the production of the first optical film layer 111 doped with ultraviolet light absorber can be achieved by the following production process: mixing the first ultraviolet light absorber and a first optical material according to a first preset ratio; processing a mixed first optical material by a polymer molding process to form the first optical film layer 111. Wherein, it is understandable that the doping ratio of the first ultraviolet light absorber doped in the first optical film layer 111 is a first preset ratio, and the first preset ratio varies according to the first ultraviolet light absorber. The specific value of the first preset ratio can be set by referring to the doping ratio above, and the first ultraviolet light absorber may be any ultraviolet light absorber described above. Wherein, the first optical material is the materials that manufacture the first optical film layer 111, and the mixed first optical material includes a first ultraviolet light absorber and a first optical material.

Wherein, the production of the second optical film layer 113 doped with ultraviolet light absorber can be achieved by the following production process: mixing the second ultraviolet light absorber and a second optical material according to a second preset ratio; processing a mixed second optical material by a polymer molding process to form the second optical film layer 113. Wherein, it is understandable that the doping ratio of the second ultraviolet light absorber doped in the second optical film layer 113 is a second preset ratio, and the second preset ratio varies according to the second ultraviolet light absorber. The specific value of the second preset ratio can be set by referring to the doping ratio above, and the second ultraviolet light absorber may be any of the ultraviolet light absorbers described above. Wherein, the second optical material is all the materials that manufacture the second optical film layer 113, and the mixed second optical material includes a second ultraviolet light absorber and a second optical material.

When the first optical film layer 111 and the second optical film layer 113 are different film layers, the first optical material and the second optical material are different. For example, the first optical material includes a cyclic olefin polymer and the second optical material includes the cellulose triacetate. When the first optical film layer 111 and the second optical film layer 113 are the same film layer, the first optical material and the second optical material are the same. For example, the first optical material and the second optical material both include the cellulose triacetate.

Regardless of whether the first optical material and the second optical material are the same, the first ultraviolet light absorber and the second ultraviolet light absorber can be same or different. For example, the first ultraviolet light absorber and the second ultraviolet light absorber are both the 2-(2′-hydroxy-5′-methylphenyl)benzotriazoles. For example, the first ultraviolet light absorber is 2-(2′-hydroxy-5′-methylphenyl)benzotriazole and the second ultraviolet light absorber is the hexamethyl phosphoryl triamine. When the first ultraviolet light absorber and the second ultraviolet light absorber are the same, for example, both the first ultraviolet light absorber and the second ultraviolet light absorber are the 2-(2′-hydroxy-5′-methylphenyl)benzotriazole, the first preset ratio and the second preset ratio may be the same, for example, both the first preset ratio and the second preset ratio are 0.2%. The first preset ratio and the second preset ratio may also be different.

In an embodiment, the first optical material and the second optical material are the same, both the first optical material and the second optical material include the cellulose triacetate. The first ultraviolet light absorber is the same as the second ultraviolet light absorber, and the first ultraviolet light absorber and the second ultraviolet light absorber include the 2-(2′-hydroxy-5′-methylphenyl)benzotriazole. Specifically, the doping ratio of the 2-(2′-hydroxy-5′-methylphenyl)benzotriazole is the optimal doping ratio of 0.3%.

Wherein, the first optical material and the second optical material use cellulose triacetate, because the ultraviolet light resistance of the TAC film made of cellulose triacetate is better than ultraviolet light resistance of the COP film. The 2-(2′-hydroxy-5′-methylphenyl)benzotriazole is selected for the first ultraviolet light absorber and the second ultraviolet light absorber, in addition to its low price and low cost, it is also because 2-(2′-hydroxy-5′-methylphenyl)benzotriazole is suitable for the cellulose acetate products, its chemical properties are stable, it is not decomposed by concentrated acid or alkali, and it has good stability in transparent products (such as the display module).

Understandably, compared with other doping ratios when the first optical film layer and the second optical film layer are other film layers (such as COP film layers), and the ultraviolet light absorber is the 2-(2′-hydroxy-5′-methylphenyl)benzotriazole, in the case where the first optical film layer 111 and the second optical film layer 113 are TAC film layers, and the corresponding doping ratio of 2-(2′-hydroxy-5′-methylphenyl)benzotriazole is the best doping ratio 0.3%, on the one hand, it can achieve the best absorption of ultraviolet light in sunlight; on the other hand, damage to the polarizing layer 112 caused by ultraviolet light in sunlight can be reduced.

In one embodiment, referring to FIG. 2, in addition to the first optical film layer 111, the polarizing layer 112, and the second optical film layer 113, the polarizer 110 also includes a hardened coating layer 114, and the hardened coating layer 114 is disposed on a side of the second optical film layer 113 away from the first optical film layer 111.

The hardened coating (HC) layer 114 is used to protect the polarizer 110, prevent the polarizer 110 from being scratched, and increase the surface hardness of the polarizer 110. The hardened coating 114 is paint-like. In practice, the hardened coating layer 114 is coated on the second optical film layer 113 and dried by a drying process to form a film layer. The film layer formed by the hardened coating layer 114 and the second optical film layer 113 is called a protective layer, and the protective layer is used to support and protect the polarizer 110 and prevent the polarizer 110 from being scratched. Specifically, the protective layer is used to protect the polarizing layer 112. Because the polarizing layer 112 is hydrophilic, it will quickly deform, shrink, relax, and decay in a hot and humid environment, and has very low strength, brittle and easy to break, and it is not convenient to use and process. Therefore, a protective layer that has high strength, heat resistance, and can reduce the penetration of ultraviolet light is compounded on the polarizing layer 112 to protect the polarizing layer 112. At the same time, the corresponding first optical film layer 111 also protects the polarizing layer 112.

When the second optical film layer 113 is a COP film layer (not doped with the ultraviolet light absorber), the protective layer formed by the second optical film layer 113 and the hardened coating layer 114 is represented by HC-COP. When the second optical film layer 113 is a TAC film layer, the protective layer formed by the second optical film layer 113 and the hardened coating layer 114 is represented by HC-TAC (undoped ultraviolet light absorber).

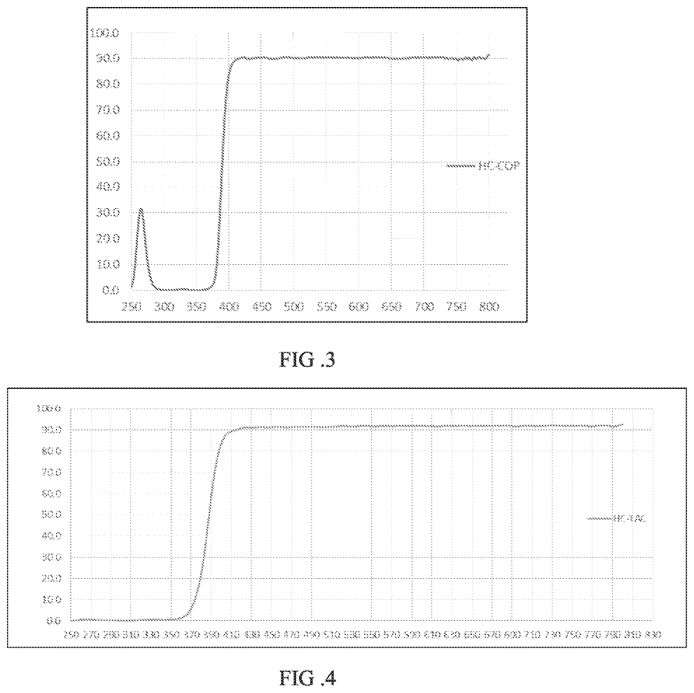

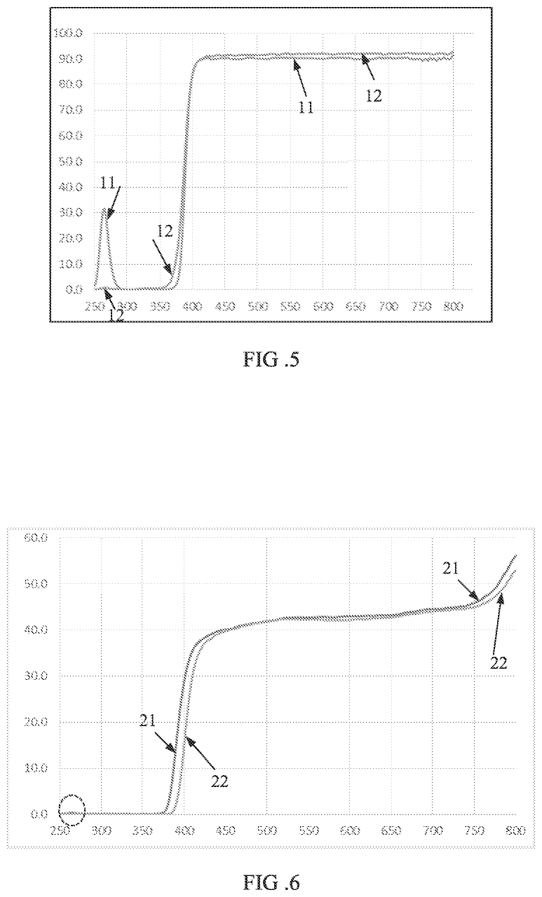

Referring to FIG. 3, FIG. 3 is a schematic diagram of a transmission spectrum of a HC-COP layer at 250 nm to 800 nm is provided by an embodiment of the present disclosure. FIG. 4 is a schematic diagram of the transmission spectrum of a HC-TAC layer at 250 nm to 800 nm is provided by an embodiment of the present disclosure. FIG. 5 is a schematic diagram of a comparison of the transmission spectrum of the HC-COP layer and the HC-TAC layer at 250 nm to 800 nm is provided by an embodiment of the present disclosure. Wherein, a curve 11 in FIG. 5 corresponds to the schematic diagram of the transmission spectrum of the HC-COP layer at 250 nm to 800 nm, and a curve 12 corresponds to the schematic diagram of the transmission spectrum of the HC-TAC layer at 250 nm to 800 nm.

Wherein, it should be noted that the experimental conditions in the embodiments of present disclosure include: a standard light source D65 was used to extract the light from 250 nm to 800 nm in the standard light source D65 using a spectrophotometer at room temperature, irradiate the corresponding film layer, and test the transmittance of the light from 250 nm to 800 nm. The experimental conditions will not be repeated in the following.

Wherein, the horizontal axis in FIG. 3, FIG. 4, and FIG. 5 represents the wavelength, and the vertical axis represents the ratio of ultraviolet light transmittance. It can be seen from FIG. 3, FIG. 4 and FIG. 5 that between 300 nm to 350 nm, both the HC-COP layer and the HC-TAC layer have very low transmittance, between 250 nm to 300 nm, the transmittance of the HC-COP layer is higher than that of the HC-TAC layer, and between 350 nm to 400 nm, the transmittance of the HC-TAC layer is slightly higher than that of the HC-COP layer. In general, between 250 nm to 400 nm, the ultraviolet light transmittance of the HC-TAC layer is lower than that of the HC-COP layer. It should be noted that what is shown in FIG. 3 and FIG. 4 is only the ultraviolet light transmittance of the single-layer protective layer HC-COP layer and HC-TAC layer. Under the HC-COP layer or the HC-TAC layer, the first optical film layer 111 is further provided to further reduce the transmittance of ultraviolet light.

Understandably, the embodiments of present disclosure have found that the ultraviolet light transmittance of the protective layer HC-TAC layer is lower than the ultraviolet light transmittance of the HC-COP layer between 250 nm and 400 nm. Therefore, the first optical film layer 111 and the second optical film layer 113 are preferentially selected as TAC film layers. At the same time, it should be noted that the first optical film layer 111 and the second optical film layer 113 may also be as described above, and other film layers with ultraviolet light resistance may also be selected.

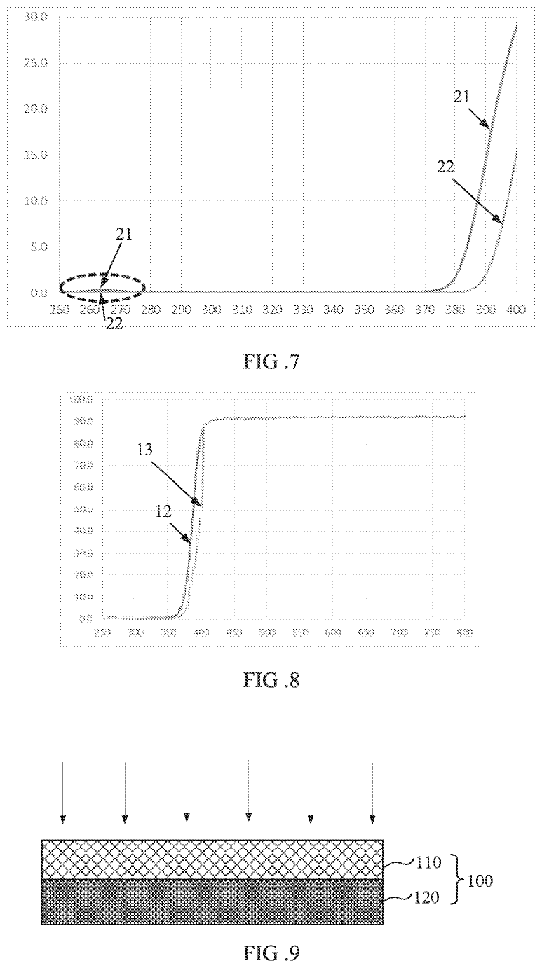

FIG. 6 is a schematic diagram of the transmission spectrum of the polarizer formed by using the HC-COP layer and the HC-TAC layer in the 250 nm to 800 nm is provided by an embodiment of the present disclosure. FIG. 7 is a schematic diagram of the transmission spectrum of the polarizer formed by the HC-COP layer and the HC-TAC layer at 250 nm to 400 nm is provided by an embodiment of the present disclosure. Wherein, a curve 21 in the figure corresponds to the schematic diagram of the transmission spectrum of the polarizer formed by the HC-COP layer, and a curve 22 corresponds to a schematic diagram of the transmission spectrum of the polarizer formed by the HC-TAC layer. Wherein, the horizontal axis represents the wavelength, and the vertical axis represents the ratio of ultraviolet light transmittance. The polarizer formed by using the HC-COP layer includes an HC-COP film layer and a polarizing layer that are stacked. The polarizer formed by using the HC-TAC layer includes an HC-TAC film layer, a polarizing layer, and a TAC layer stacked in sequence. The formed polarizer also includes film layers such as a first glue layer, a compensation layer, and a second glue layer stacked in sequence.

It can be seen from FIG. 6 and FIG. 7 that between 250 nm to 280 nm, the ultraviolet light transmittance of the polarizer formed by HC-COP is greater than that of the polarizer formed by HC-TAC, and between 360 nm to 400 nm, the ultraviolet light transmittance of the polarizer formed by HC-COP is also greater than that of the polarizer formed by HC-TAC. It is further confirmed from FIGS. 6 and 7 that the ultraviolet light transmittance of the polarizer made of the HC-TAC layer is lower than that of the polarizer made of the HC-COP. That is to say, the ultraviolet light transmittance of the polarizer made of the HC-TAC layer and the TAC film layer on both sides of the polarizing layer is lower than that of the polarizer made of the HC-COP layer on one side of the polarizing layer. Especially in the range of 250 nm to 350 nm, there are no bumps, the transmittance is low, and the transmittance in the range of 350 nm to 400 nm is also low. The closer to 250 nm, the higher the relative frequency of the ultraviolet light, the stronger the energy, and the greater the damage to the polarizer. The polarizer made of HC-TAC layer and TAC film on both sides of the polarizing layer is in the range of 250 nm to 350 nm. There are no bumps inside, which can avoid damage to the display module caused by high-energy ultraviolet light.

In the embodiment of the present disclosure, a hardened coating layer 114 is provided on one side of the second optical film layer 113. In addition to protecting the polarizer 110, a hardened coating layer 114 is added to increase the ultraviolet light resistance of the polarizer 110 and improve the color temperature stability of the polarizer 110 before and after sunlight exposure.

In an embodiment, at least one of the first optical film layer 111, the polarizing layer 112, the second optical film layer 113, and the hardened coating layer 114 is doped with an ultraviolet light absorber. The doped ultraviolet light absorber can further absorb the ultraviolet light in the sunlight, thereby reducing the color temperature change of the polarizer 110 after the sunlight is irradiated, and improving the color temperature stability of the polarizer 110 before and after the sunlight.

Wherein, when the ultraviolet light absorber is doped in at least two of the first optical film layer 111 and/or the polarizing layer 112 and/or the second optical film layer 113 and/or the hardened coating layer 114, the doped ultraviolet light absorbers can be the same ultraviolet light absorbers or different kinds of ultraviolet light absorbers. When the ultraviolet light absorber doped in the first optical film layer 111 and/or the polarizing layer 112 and/or the second optical film layer 113 and/or the hardened coating layer 114 is the same ultraviolet light absorber, the doping ratios of the ultraviolet light absorbers in the corresponding different film layers can be the same or different. When the ultraviolet light absorbers doped in the first optical film layer 111 and/or the polarizing layer 112 and/or the second optical film layer 113 and/or the hardened coating layer 114 are different ultraviolet light absorbers, depending on the ultraviolet light absorber, the corresponding doping ratio is also different. For specific ultraviolet light absorbers and corresponding doping ratios, please refer to the corresponding description above, which will not be repeated here.

Wherein, forming the hardened coating layer 114 doped with ultraviolet light absorber on the second optical film layer 113 can be achieved by the following manufacturing process: dissolving a third ultraviolet light absorber into a hardened coating material according to a third preset ratio; coating a dissolved hardened coating material on the second optical film layer 113 (a side away from the polarizing layer), and drying it by a drying process, to form the hardened coating layer 114 on the second optical film layer 113. Wherein, the second optical film layer 113 in the process flow may be doped with ultraviolet light absorbers, or may not be doped with ultraviolet light absorbers. Specifically, for the process flow of manufacturing the second optical film layer 113 doped with ultraviolet light absorber, please refer to the above description, which will not be repeated here.

Wherein, the third ultraviolet light absorber can be any ultraviolet light absorber described above, correspondingly, the doping ratio of the third ultraviolet light absorber is the third preset ratio. The value of the third preset ratio can be set by referring to the doping ratio of the ultraviolet light absorber above. The hardened coating materials include materials configured to manufacture the hardened coating layer, and the dissolved hardened coating material includes a hardened coating material and a third ultraviolet light absorber.

In an embodiment, both the first optical film layer 111 and the second optical film layer 113 are TAC film layers. The first optical film layer 111, the second optical film layer 113 and the hardened coating layer 114 are all doped with ultraviolet light absorbers, and the ultraviolet light absorber is 2-(2′-hydroxy-5′-methylphenyl)benzotriazole. Correspondingly, the doping ratio of 2-(2′-hydroxy-5′-methylphenyl)benzotriazole is the optimal doping ratio of 0.3%. For determination of the TAC film layer and the specific ultraviolet light absorber (2-(2′-hydroxy-5′-methylphenyl)benzotriazole), please refer to the above description, which will not be repeated here.

Understandably, compared with other doping ratios when the first optical film layer and the second optical film layer are other film layers (such as COP film layers), the first optical film layer and/or the second optical film layer and/or the hardware coating are not doped with ultraviolet light absorbers, and the ultraviolet light absorber is the 2-(2′-hydroxy-5′-methylphenyl)benzotriazole, in this embodiment, in the case where the first optical film layer 111 and the second optical film layer 113 use TAC film layers, the first optical film layer 111, the second optical film layer 113 and the hardened coating layer 114 are all doped with 2-(2′-hydroxy-5′-methylphenyl)benzotriazole, and the doping ratio is the optimal doping ratio 0.3%, on the one hand, it can achieve the best absorption of ultraviolet light in sunlight; on the other hand, doping the second optical film layer 113 and hardened coating 114 of the polarized layer 112 near the incoming side of sunlight with the optimal doping ratio of 2-(2′-hydroxy-5′-methylphenyl)benzotriazole, the damage to the polarized layer 112 caused by the ultraviolet light from sunlight can be minimized.

FIG. 8 is a schematic diagram of the comparison of the corresponding ultraviolet light transmittance when the HC-TAC layer is doped with ultraviolet light absorber or not is provided by an embodiment of the present disclosure. The curve 12 in FIG. 8 corresponds to the ultraviolet light transmittance when the HC-TAC layer is not doped with ultraviolet light absorber (both the hardened coating 114 and the second optical film layer 113 layer are not doped with ultraviolet light absorber). The curve 13 corresponds to the ultraviolet light transmittance when HC-TAC is doped with ultraviolet light absorber (both the hardened coating 114 and the second optical film layer 113 are doped with ultraviolet light absorber). The ultraviolet light absorber doped is the 2-(2′-hydroxy-5′-methylphenyl)benzotriazole, and the doping ratio is the optimal doping ratio of 0.3%.

Please refer to FIG. 8 and FIG. 4, as can be seen from FIG. 8 and FIG. 4, the ultraviolet light transmittance of the HC-TAC layer without ultraviolet light absorber doping is higher from 350 nm to 395 nm (in UV-A band). Wherein, the ultraviolet light transmittance reaches 58.5% @390 nm, 71.1% @394 nm, and even 89.4% at @410 nm. The HC-TAC layer doped with ultraviolet light absorber has lower ultraviolet light transmittance in the wavelengths from 250 nm to 400 nm. In particular, the decrease of ultraviolet light transmittance is more obvious between 350 nm and 400 nm. This is because the HC-TAC layer without ultraviolet light absorber doping has higher ultraviolet light transmittance between 350 nm to 400 nm wavelength band itself, and after doping with ultraviolet light absorber, the decrease in transmittance between 350 nm to 400 nm wavelength band is more obvious through the absorption of ultraviolet light by ultraviolet light absorber. Wherein, the ultraviolet light transmittance of @390 nm is reduced from 58.5% to 24.6%, and the ultraviolet light transmittance of @394 nm is reduced from 71.1% to 32.2%.

It can also be seen from FIG. 7 that in the embodiment of the present disclosure, an ultraviolet light absorber is doped in the HC-TAC layer, which makes it possible to achieve lower ultraviolet light transmittance in the UV-A, UV-B, and UV-C bands, and has a good ultraviolet light blocking ability in the UV-A, UV-B and UV-C bands. Especially in the UV-A band (such as 350 nm to 400 nm), the corresponding ultraviolet light transmittance decreases more obviously.

The ultraviolet light transmittance of the protective layer formed by doping the ultraviolet absorber in the HC-TAC layer (the hardened coating layer 114 and the second optical film layer 113 are both doped with ultraviolet absorber) can reach the following level: 292 nm Tr≤0.3%, 280 nm Tr≤0.3%, 270 nm Tr≤0.7%, 250 nm Tr≤0.2%. Correspondingly, the transmittance of the polarizer 110 (the polarizer includes the HC-TAC layer and the TAC layer doped with ultraviolet light absorbers on both sides of the polarizing layer) reaches: 292 nm Tr≤0.15%, 280 nm Tr≤0.15%, 270 nm Tr≤0.15%, 260 nm Tr≤0.15%, 250 nm Tr≤0.15%, 300-380 nm any wavelength Tr≤0.5%. Wherein, the ultraviolet light transmittance of the protective layer is represented by Tr. For example, 292 nm Tr≤0.3% means that the ultraviolet light transmittance Tr≤0.3% at 292 nm. Wherein, for the transmittance of larger wavelengths in UV-A, the ultraviolet transmittance of the protective layer can reach the following level: 390 nm Tr≤24.6%, 394 nm Tr≤32.2%. It has lower transmittance in the 250 nm to 400 nm waveband.

In this embodiment, the second optical film layer 113 and the hardened coating layer 114 are doped with ultraviolet light absorbers. In this way, there are more ultraviolet light absorbers in the protective layer, which can absorb more UV-A, UV-B, and UV-C ultraviolet light in the sunlight, and greatly reduce the transmittance of ultraviolet light in the protective layer. The color temperature change amount of the polarizer 110 before and after sunlight exposure is greatly reduced, and the ultraviolet light resistance performance of the polarizer 110 is improved. If both the first optical film layer 111 and the polarizing layer 112 are doped with ultraviolet light absorbers, the color temperature change can be further reduced, the ultraviolet light resistance of the polarizer 110 can be further improved, and the display effect of the display module can be improved.

In one embodiment, referring to FIG. 1 and FIG. 0.2, the polarizer 110 further includes a first adhesive layer 115, a compensation layer 116, and a second adhesive layer 117 stacked in sequence. Wherein, the first optical film layer 111 is disposed on the side of the second adhesive layer 117 away from the first adhesive layer 115.

Wherein, the first adhesive layer 115 may be a first pressure-sensitive adhesive (PSA) layer, and the second adhesive layer 117 may also be a second pressure-sensitive adhesive (PSA) layer. The first adhesive layer 115 and the second adhesive layer 117 are made of a type of adhesive that is sensitive to pressure, and are used to bond adjacent film layers together.

The compensation layer 116 is also referred to as a filter layer, and is used to convert linearly polarized light into circularly polarized light.

Sunlight enters from one side of the hardened coating layer 114, passes through the second optical film layer 113, and enters the polarizing layer 112. After the light enters the polarizing layer 112, polarized light is formed, and then passes through the first optical film layer 111 and the second adhesive layer 117 to further reduce the amount of ultraviolet light entering the compensation layer 116. Then enter the compensation layer 116 to form circularly polarized light. Finally, it passes through the first adhesive layer 115 and is emitted from the polarizer.

In one embodiment, one of the first optical film layer 111, the polarizing layer 112, the second optical film layer 113, the hardened coating layer 114, the first glue layer 115, the compensation layer 116 and the second glue layer 117 is doped with an ultraviolet light absorber. The doped ultraviolet light absorber further absorbs the ultraviolet light in the sunlight, the color temperature change of the polarizer 110 after sunlight exposure is further reduced, the color temperature stability of the polarizer 110 before and after sunlight exposure is improved, and the display effect of the display module is improved.

Wherein, when the ultraviolet light absorber is doped in at least two of the first optical film layer 111 and/or polarizing layer 112 and/or second optical film layer 113 and/or hardened coating 114 and/or first adhesive layer 115 and/or compensating layer 116 and/or second adhesive layer 117, the ultraviolet light absorber doped may be the same ultraviolet light absorber or different ultraviolet light absorber.

When the ultraviolet light absorber doped in the first optical film layer 111 and/or the polarizing layer 112 and/or the second optical film layer 113 and/or the hardened coating layer 114 and/or the first adhesive layer 115 and/or the compensation layer 116 and/or the second adhesive layer 117 is the same ultraviolet light absorber, the doping ratios of the ultraviolet light absorbers in the corresponding different film layers can be the same or different.

When the ultraviolet light absorber doped in the first optical film layer 111 and/or the polarizing layer 112 and/or the second optical film layer 113 and/or the hardened coating layer 114 and/or the first adhesive layer 115 and/or the compensation layer 116 and/or the second adhesive layer 117 is the different ultraviolet light absorber, the corresponding doping ratio is also different according to the different ultraviolet light absorbers. For specific ultraviolet light absorbers and corresponding doping ratios, please refer to the corresponding description above, which will not be repeated here.

In some embodiment, when the first optical film layer 111, the polarizing layer 112, the second optical film layer 113, the hardened coating layer 114, the first adhesive layer 115, the compensation layer 116 and the second adhesive layer 117 are both doped with ultraviolet light absorbers, and the doping ratio of the ultraviolet light absorber is the optimal doping ratio, the polarizing layer is doped with more ultraviolet light absorbers. The ultraviolet light from the sunlight is absorbed to the greatest extent, the color temperature change of the polarizer 110 is reduced, the ultraviolet resistance performance of the polarizer 110 is improved, and the display effect of the display module is improved.

In one embodiment, when the first optical film layer 111, the polarizing layer 112, the second optical film layer 113, the hardened coating layer 114, the first adhesive layer 115, the compensation layer 116 and the second adhesive layer 117 are doped with ultraviolet light absorbers 2-(2′-hydroxy-5′-methylphenyl)benzotriazole, the first optical film layer 111 and the second optical film layer 113 are both TAC film layers, and the doping ratio of doped 2-(2′-hydroxy-5′-methylphenyl)benzotriazole is the best doping ratio, the ultraviolet light in the sunlight can be absorbed to the greatest extent. The color temperature change of the polarizer 110 is reduced to the greatest extent, the ultraviolet light resistance performance of the polarizer 110 is maximized, the stability of the polarizer 110 is maximized, and the display effect and stability of the display module are improved.

By disposing the first optical film layer 111 and the second optical film layer 113 on opposite sides of the polarizing layer 112, and doping an ultraviolet light absorber in at least one of the first optical film layer 111, the polarizing layer 112, the second optical film layer 113, the hardened coating layer 114, the first adhesive layer 115, the compensation layer 116 and the second adhesive layer 117, the amount of ultraviolet light passing through the polarizer 110 is reduced, the ultraviolet light transmittance of the polarizer 110 is reduced, the color temperature change of the polarizer 110 after sunlight exposure is reduced, and the solar resistance performance of the display module 100 is improved. If the display module 100 is an organic light-emitting diode display screen, it will further reduce the amount of ultraviolet light entering the EL material in the display panel, reduce the damage of ultraviolet light to the EL material, enhance the protective ability of the polarizer to the EL material, and reduce the color temperature change of the EL material after sunlight exposure, thereby improving the ultraviolet light resistance of the display module and improving the display effect of the display module.

FIG. 9 is a schematic diagram of the structure of the display module is provided by an embodiment of the present disclosure. Referring to FIG. 0.9, the display module 100 includes a display panel 120 and a polarizer 110 that are stacked. Sunlight enters from the side of the polarizer 110 (the arrow direction in FIG. 9 is the incident direction of the sun light).

Wherein, the polarizer 110 is the polarizer described in the above embodiment. The first adhesive layer 115 of the polarizer 110 is attached to the display panel 120. The compensation layer 116, the second adhesive layer 117, the first optical film layer 111, the polarizing layer 112, the second optical film layer 113, and the hardened coating layer 114 (if any) of the polarizer 110 gradually move away from the display panel 120 in sequence. Specifically, please refer to the corresponding description in the above embodiment for the relevant information such as the respective film layers in the polarizer 110, which will not be repeated here.

In one embodiment, the display panel 120 is a display panel including an OLED display array (the display panel includes an EL material), and correspondingly, the display module 100 is an OLED display screen.

Wherein, since the polarizer 110 can reduce the transmittance of ultraviolet light, the amount of ultraviolet light entering the polarizing structure can be reduced, and the color temperature change amount of the polarizer before and after sunlight exposure can be reduced. At the same time, the amount of ultraviolet light entering the EL material of the display panel is reduced, the damage of ultraviolet light to the EL material is reduced, and the protective ability of the polarizer 110 to the EL material is further enhanced. The color temperature change of the EL material after sunlight exposure is reduced, thereby improving the sunlight resistance (ultraviolet light resistance) performance of the display module, and improving the display effect.

In some embodiment, the display panel 120 may also be a display panel including an array substrate, a color filter substrate, a liquid crystal molecular layer, etc. Alternatively, the display panel 120 is a display panel including a color filter on array (COA) substrate. Correspondingly, the display module 100 is a liquid crystal display. In some other embodiments, the display panel 120 may also be other types of display panels, and the display module 100 is a display screen corresponding to the display panel 120.

Correspondingly, the ultraviolet light transmittance is reduced by the polarizer 110, the color temperature change amount of the polarizer 110 before and after sunlight exposure is reduced, the solar light resistance (ultraviolet light resistance) performance of the display module 100 is improved, and the display effect is improved.

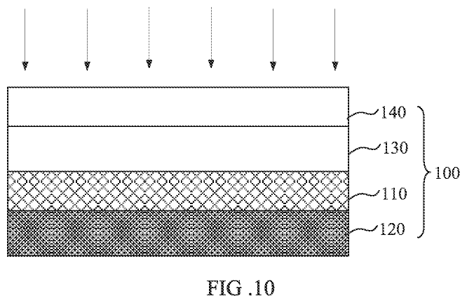

FIG. 10 is a schematic diagram of the structure of the display module provided by an embodiment of the present disclosure. Referring to FIG. 0.10, the display module 100 includes a display panel 120, a polarizer 110, an optically clear adhesive (OCA) 130 and a cover glass (CG) 140 which are sequentially stacked and arranged. Wherein, the protective cover 140 is on the side close to the viewer, that is, the protective cover 140 is located on the side where sunlight enters (the arrow direction in FIG. 10 is the incident direction of sunlight).

For the display panel 120 and the polarizer 110 in this embodiment, please refer to the corresponding descriptions in the foregoing embodiment, which will not be repeated here.

It should be noted that for the above method embodiments, for the sake of simple description, they are all expressed as a series of action combinations. However, those of ordinary skill in the art should know that the present disclosure is not limited by the described sequence of actions. According to the present disclosure, certain steps can be performed in other order or simultaneously. Secondly, those of ordinary skill in the art should also be aware that the embodiments described in the specification are all preferred embodiments, and the actions and modules involved are not necessarily required by the present disclosure.

In the above mentioned embodiments, the description of each embodiment has its own emphasis. For parts that are not described in detail in an embodiment, reference may be made to related descriptions of other embodiments.

The embodiments of the present disclosure are described in detail above, specific examples are used to explain the principle and implementation of the present disclosure, the descriptions of the above embodiments are only used to help understand the present disclosure technical solutions and their core ideas. Those of ordinary skill in the art should understand that they can still modify the technical solutions described in the foregoing embodiments, or equivalently replace some of the technical features. These modifications or replacements, and the essence of the corresponding technical solutions does not deviate from the scope of the technical solutions of the embodiments of the present disclosure.

What is claimed is:

1. A display module, comprising a polarizer; wherein the polarizer comprises a first optical film layer, a polarizing layer and a second optical film layer stacked in sequence; and the first optical film layer and the second optical film layer have ultraviolet light resistance.

2. The display module of claim 1, wherein the first optical film layer and the second optical film layer are film layers made of same material.

3. The display module of claim 2, wherein the material configured to manufacture the first optical film layer and the second optical film layer comprises cellulose triacetate.

4. The display module of claim 1, wherein the polarizer further comprises a hardened coating layer; and the hardened coating layer is disposed on a side of the second optical film layer away from the first optical film layer.

5. The display module of claim 4, wherein the polarizer further comprises a first glue layer, a compensation layer and a second glue layer stacked in sequence; and the first optical film layer is disposed on a side of the second glue layer away from the first glue layer.

6. The display module of claim 5, wherein one of the first optical film layer, the polarizing layer, the hardened coating layer, the second optical film layer, the first glue layer, the compensation layer and the second glue layer is doped with an ultraviolet light absorber.

7. The display module of claim 1, wherein the display module further comprises a display panel, and the polarizer is disposed on the display panel.

8. The display module of claim 6, wherein the ultraviolet light absorber comprises benzotriazole compound.

9. The display module of claim 8, wherein the benzotriazole compound comprises a 2-(2′-hydroxy-3′,5′-di-tert-phenyl)-5-chloro-benzotriazole, and a corresponding doping ratio is 1-3%; or
the benzotriazole compounds comprises a 2-(2′-hydroxy-5′-methylphenyl) benzotriazole, and a corresponding doping ratio is 0.1-0.5%.

10. The display module of claim 9, wherein an optimal doping ratio of the 2-(2′-hydroxy-3′,5′-di-tert-phenyl)-5-chloro-benzotriazole is 2%, and an optimal doping ratio of the 2-(2′-hydroxy-5′-methylphenyl)benzotriazole is 0.3%.

11. The display module of claim 10, wherein a material configured to manufacture the first optical film layer and the second optical film layer comprises cellulose triacetate; the first optical film layer, the second optical film layer and the hardened coating layer are doped with the ultraviolet light absorber; the ultraviolet light absorber comprises the 2-(2′-hydroxy-5′-methylphenyl) benzotriazole, and the doping ratio of the 2-(2′-hydroxy-5′-methylphenyl) benzotriazole is a corresponding optimal doping ratio.

12. The display module of claim 6, wherein the ultraviolet light absorber comprises a light stabilizer.

13. The display module of claim 12, wherein the light stabilizer comprises a 4-benzoyloxy-2,2,6,6-tetramethylpiperidine, and a corresponding doping ratio is 0-1%; or
the light stabilizer comprises a hexamethylphosphoric triamide, and a corresponding doping ratio is 0-0.5%.

14. The display module of claim 13, wherein an optimal doping ratio of the 4-benzoyloxy-2,2,6,6-tetramethylpiperidine is 0.7%, and an optimal doping ratio of the hexamethylphosphoric triamide is 0.4%.

15. The display module of claim 6, wherein the first optical film layer is doped with first ultraviolet light absorber; a process of manufacturing the first optical film layer doped with the first ultraviolet light absorber comprises:
mixing the first ultraviolet light absorber and a first optical material according to a first preset ratio;
processing a mixed first optical material by a polymer molding process to form the first optical film layer;
wherein the first ultraviolet light absorber is one of the ultraviolet light absorber, the first optical material is a material configured to manufacture the first optical film layer that is not doped with the first ultraviolet light absorber, and the mixed first optical material comprises the first ultraviolet light absorber and the first optical material.

16. The display module of claim 15, wherein the first optical material comprises cycloolefin polymer or cellulose triacetate.

17. The display module of claim 6, wherein the second optical film layer is doped with an second ultraviolet light absorber; a process of manufacturing the second optical film layer doped with the second ultraviolet light absorber comprises:
mixing the second ultraviolet light absorber and a second optical material according to a second preset ratio;
processing a mixed second optical material by a polymer molding process to form the second optical film layer;
wherein the second ultraviolet light absorber is one of the ultraviolet light absorber, the second optical material is a material configured to manufacture the second optical film layer that is not doped with the second ultraviolet light absorber, and the mixed second optical material comprises the second ultraviolet light absorber and the second optical material.

18. The display module of claim 6, wherein the hardened coating layer is doped with the ultraviolet light absorber; a process of forming the hardened coating layer doped with the ultraviolet light absorber on the second optical film layer comprises:
dissolving a third ultraviolet light absorber into a hardened coating material according to a third preset ratio;
coating a dissolved hardened coating material on a side of the second optical film layer away from the polarizing layer, and drying it by a drying process, to form the hardened coating layer on the second optical film layer;
wherein the third ultraviolet light absorber is one of the ultraviolet light absorber, the hardened coating material is a material configured to manufacture the hardened coating layer that is not doped with the third ultraviolet light absorber, and the dissolved hardened coating material comprises the hardened coating material and the third ultraviolet light absorber.

19. The display module of claim 7, wherein the display module further comprises an optically clear adhesive layer and a protective cover plate; the display panel, the polarizer, the optically clear adhesive layer and the protective cover plate are stacked in sequence.

20. The display module of claim 7, wherein the display panel comprises an organic light-emitting diode display array.
